(19) United States
(12) Patent Application Publication
(10) Pub. No.: US 2025/0386564 A1
(43) Pub. Date: Dec. 18, 2025

(54) PATTERNED TRENCHES FOR NANORIBBON-BASED TRANSISTOR REGISTRATION AND ALIGNMENT

(71) Applicant: Intel Corporation, Santa Clara, CA (US)

(72) Inventors: Aryan Navabi Shirazi, Portland, OR (US); James Bondi, Beaverton, OR (US); Curtis Ward, Forest Grove, OR (US)

(73) Assignee: Intel Corporation, Santa Clara, CA (US)

(21) Appl. No.: 18/740,820

(22) Filed: Jun. 12, 2024

(51) Int. Cl. H01L 29/06; H01L 21/02; H01L 29/66

(52) U.S. Cl. CPC H10D 62/118; H01L 21/02532; H10D 30/024; H10D 30/0321

(57) ABSTRACT

A method of fabricating an integrated circuit (IC) structure including patterned trenches for nanoribbon-based transistors for registration and alignment may involve etching an opening in a substrate, where the opening may be used for alignment of an implant process. Instead of filling the opening (e.g., with polysilicon), after implant, a stack of alternate layers of semiconductor materials may be provided both over the substrate and in the opening. The method may then involve patterning the stack into fins, where patterning the stack involves removing the semiconductor material from the opening. The opening may then be filled with an insulator material, and nanoribbon-based transistors may be formed from the fins. In one example, the resulting IC structure includes an insulator-filled trench in the substrate in a plane below the nanoribbon stacks.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon-based field-effect transistor (FET), according to some embodiments of the present disclosure.

FIGS. 2A and 2B are top-down views of IC structures that include patterned trenches for nanoribbon-based transistor registration and alignment, according to one embodiment of the present disclosure.

FIG. 3A illustrates a top-down view of an example of a die including patterned trenches for nanoribbon-based transistor registration and alignment, in accordance with some embodiments.

FIG. 3B illustrates an example cross-sectional view of a portion of the die of FIG. 3A, according to one embodiment of the present disclosure.

FIG. 4 is a flow diagram of an example method for fabricating an IC structure including patterned trenches for nanoribbon-based transistor registration and alignment, in accordance with some embodiments.

FIGS. 5-7, 8A-8C, 9A-9C, and 10A-10B provide cross-sectional side views at various stages in the fabrication of an example IC structure according to the method of FIG. 4, in accordance with some embodiments.

FIG. 11 is a top view of a wafer and dies that may include any of the IC devices disclosed herein, in accordance with any of the embodiments disclosed herein.

FIG. 12 is a side, cross-sectional view of an IC package that may include any of the IC devices disclosed herein, in accordance with various embodiments.

FIG. 13 is a side, cross-sectional view of an IC device assembly that may include any of the IC devices disclosed herein, in accordance with any of the embodiments disclosed herein.

FIG. 14 is a block diagram of an example electrical device that may include any of the IC devices disclosed herein, in accordance with any of the embodiments disclosed herein.

### DETAILED DESCRIPTION

Disclosed herein are integrated circuit (IC) structures including patterned trenches for nanoribbon-based transistor registration and alignment. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Complementary Metal-Oxide-Semiconductor (CMOS) refers to a type of integrated circuit design that uses complementary and symmetrical pairs of P-type and N-type metal-oxide-semiconductor field-effect transistors (MOSFETs) for logic gates and other digital circuits. Typically, in order to form N-type transistors or P-type transistors, dopants are added to a semiconductor material to introduce either additional holes or additional electrons into the crystal lattice. For example, N-type dopants are dopants deliberately added to a semiconductor material (e.g., to source or drain (S/D) regions of an N-type transistor) to introduce additional electrons into the crystal lattice. N-type dopants are also known as “donor” impurities. On the other hand, P-type dopants are dopants deliberately added to a semiconductor material (e.g., to S/D regions of a P-type transistor) to introduce additional holes into the crystal lattice. P-type dopants are also known as “acceptor” impurities.

Dopants may be introduced to a region of semiconductor material via an implant process. The implant process itself does not typically result in any optically detectable features to enable alignment of subsequent processes (e.g., fin patterning). Therefore, registration marks (also referred to as alignment marks) may be formed prior to implant to enable alignment of the implant process and subsequent processes. Registration marks are typically physical topographical features that are detectable by process equipment in order to perform a process in a desired area on a wafer. Alignment refers to the process of positioning or aligning a wafer or a feature on a wafer to a processing tool. Registration refers to a measure of the actual alignment achieved between successive features or patterns (e.g., a measure of how well various features or patterns are aligned with one another). Well-defined registration marks can improve alignment and registration, which is important for device functionality and yield.

In one example, forming a registration mark prior to implant (e.g., for forming nanoribbon-based transistors) may involve embedding a region of polycrystalline silicon (polysilicon) in a substrate by etching a trench in the substrate and depositing polysilicon in the trench. Although the embedded polysilicon region may be detectable by the implant process equipment, the process of embedding the polysilicon region in the substrate can be expensive and time-consuming. After implant, alternate layers of a first semiconductor material and a second semiconductor material may be deposited, which may subsequently be etched in order to form nanoribbon stacks. In some cases, the location of the registration marks may not be clearly detectable by process equipment after deposition of the stack of alternating layers of semiconductor material. Thus, the embedded polysilicon registration marks are not only expensive to form in terms of cost and time, the resulting registration marks may be ineffective for enabling alignment of processes after implant.

In contrast, in accordance with examples described herein, IC structures including patterned trenches for nanoribbon-based transistors registration and alignment may enable alignment of both implant and subsequent processes (e.g., fin patterning). In one example, a method of fabricating an IC structure including patterned trenches for nanoribbon-based transistors for registration and alignment may involve etching a substrate (e.g., through an opening in a mask) to form an opening (e.g., trench) in the substrate. Instead of first filling the opening (e.g., with polysilicon), a stack of alternate layers of a first semiconductor material and a second semiconductor material may be provided both over the substrate and in the second. The method may then involve patterning the stack into fins, where patterning the stack may result in removal of the alternate layers of the first semiconductor material and the second semiconductor material from the opening. The second opening may then be filled with an insulator material, and nanoribbon-based transistors may be formed from the fins. In one example, the resulting IC structure includes an insulator-filled trench in the substrate in a plane below the nanoribbon stacks.

IC structures as described herein, in particular IC structures including patterned trenches for nanoribbon-based transistor registration and alignment, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures including patterned trenches for nanoribbon-based transistor registration and alignment as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

IC structures including patterned trenches for nanoribbon-based transistor registration and alignment may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Devices in the device region may be electrically isolated from one another by any suitable insulator material.

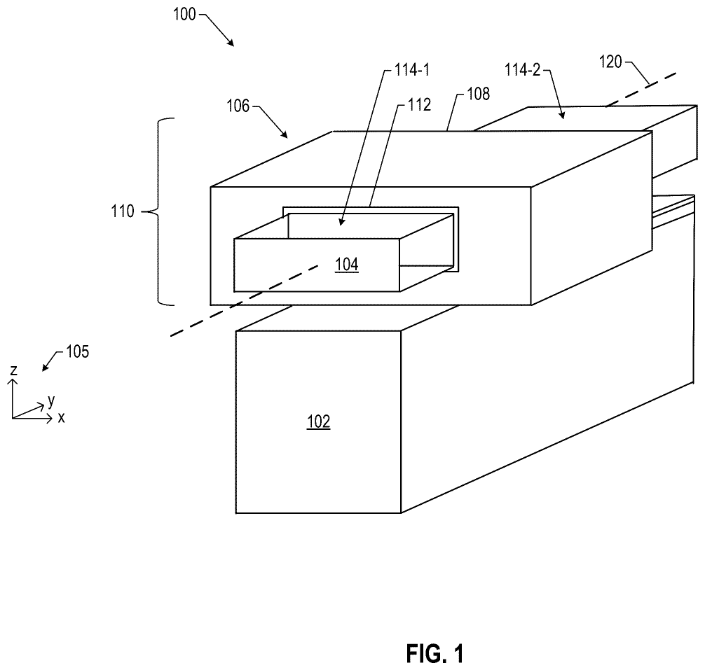

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2 (referred to herein as simply “S/D regions” 114), on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

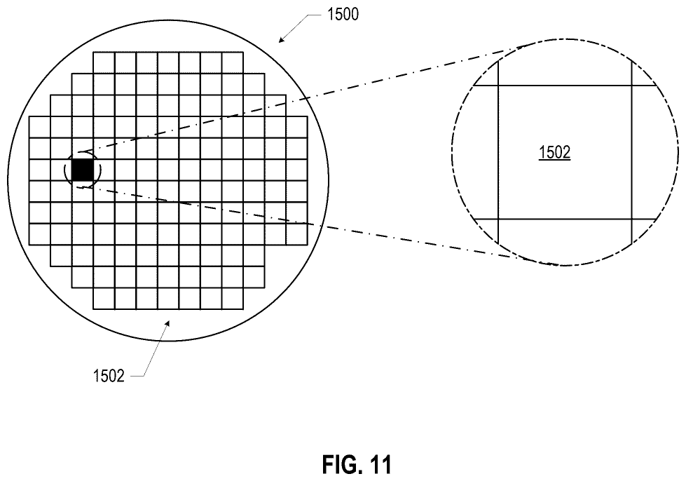

Implementations of the present disclosure may be formed or carried out on any suitable support 102, such as a substrate, a die, a wafer, or a chip. The support 102 may, e.g., be the wafer 1500 of FIG. 11, discussed below, and may be, or be included in, a die, e.g., the singulated die 1502 of FIG. 11, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system) may be at least about 3 times larger than a height or thickness of the nanoribbon 104 (i.e., a dimension measured in a plane perpendicular to the support 102, e.g., along the z-axis of the coordinate system), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group Ill of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on backend fabrication to avoid damaging other components, e.g., frontend components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabrication of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

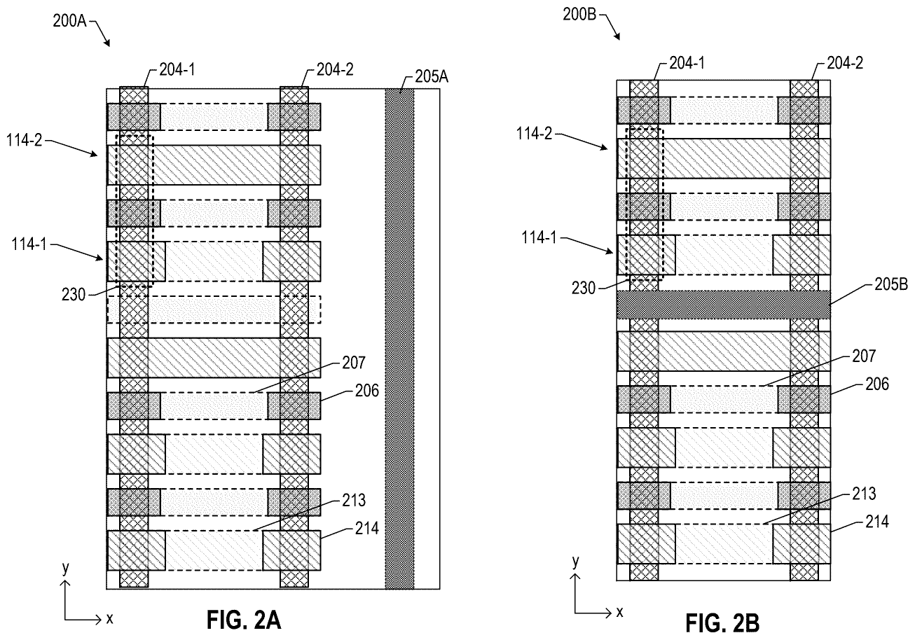

FIGS. 2A and 2B are top-down views of IC structures 200A and 200B that may include patterned trenches for nanoribbon-based transistor registration and alignment, according to one embodiment of the present disclosure. Some of the materials are not shown in the top-down view in order to not obscure the drawing.

As shown in FIGS. 2A and 2B, the IC structures 200A, 200B may include two nanoribbon stacks 204-1 and 204-2 (collectively referred to as “nanoribbon stacks 204”), if the transistors to be implemented in the IC structures 200A, 200B are nanoribbon transistors such as the one illustrated in FIG. 1. Alternatively, what is now shown as nanoribbon stacks 204-1 and 204-2 could be fins, if the transistors to be implemented in the IC structures 200A, 200B are FinFETs. The nanoribbon stacks 204 may include stacks of one or more nanoribbons 104 as described above and may be provided over a support such as the support 102 (not specifically shown in FIGS. 2A-2B). The nanoribbon stacks 204 may extend substantially parallel to one another, e.g., along the y-axis of the coordinate system 105, consistent with the illustration of FIG. 1. Metal gate lines 207 (shown in FIGS. 2A-2B to be within dashed contours) and S/D contact lines 213 may extend substantially perpendicular to the nanoribbon stacks 204 and substantially parallel to one another, e.g., along the x-axis of the coordinate system 105. FIGS. 2A-2B illustrates that the metal gate lines 207 and the S/D contact lines 213 may be provided in an alternating manner. The gate contacts 206 are in conductive contact with the gate stacks 106 (which are underneath the gate contacts 206 and, therefore, not seen in the view of FIGS. 2A-2B) provided over channel portions of the nanoribbon stacks 204, providing electrical connectivity to the gates of the nanoribbon transistors. Thus, portions of the gate contacts 206 intersecting the gate stacks 106 are in conductive contact with the gate stacks 106 and serve as gate contacts for the transistors.

The S/D contacts 214 are provided over S/D regions 114 (which are underneath the S/D contacts 214 and, therefore, not seen in the view of FIGS. 2A-2B) of the nanoribbon stacks 204, providing electrical connectivity to the S/D regions 114 of the nanoribbon transistors. Thus, portions of the S/D contacts 214 intersecting the S/D regions 114 are in conductive contact with the S/D regions 114 and serve as S/D contacts for the transistors. The dotted contour 230 indicates the approximate location of a nanoribbon-based transistor.

FIGS. 2A and 2B also include registration marks 205A, 205B. FIG. 2A illustrates a registration mark 205A that extends substantially parallel to the nanoribbon stacks 204-1, 204-2 (e.g., along the y-axis as shown in FIGS. 2A, 2B). FIG. 2B illustrates a registration mark 205B that extends substantially orthogonally to the nanoribbon stacks 204-1, 204-2 (e.g., along the x-axis as shown in FIGS. 2A, 2B). Therefore, the registration mark 205A of FIG. 2A does not intersect the nanoribbon stacks 204-1, 204-2, whereas the registration mark 205B of FIG. 2B does intersect the nanoribbon stacks 204-1, 204-2. As explained in further detail below, in some examples, the registration marks 205A, 205B are “buried” registration marks in the sense that they are regions that are later covered by subsequent processes, and therefore may not be visible from a top-down view of a final IC structure. In one example, the registration marks 205A, 205B are openings (e.g., trenches) in the substrate in a plane below the one or more nanoribbons (e.g., in a plane parallel with the x-y plane shown in FIGS. 2A, 2B below a bottom nanoribbon of the nanoribbon stacks 204-1, 204-2), where the openings are filled with an insulator material. Thus, unlike in an IC structure that includes an embedded polysilicon region in the substrate to act as a registration mark, the registration marks 205A, 205B are filled with a continuous portion of an insulator material without a polysilicon layer.

While a particular arrangement of gate stacks 106, metal gate lines 207, gate contacts 206, S/D contact lines 213, and S/D contacts 214 is shown in FIG. 1 and FIGS. 2A-2B, in other embodiments, these elements may be arranged differently within the IC structures 200A, 200B. Furthermore, the shape, location, and orientation of the registration marks 205A, 205B shown in FIGS. 2A and 2B are examples, and other examples may include different or additional registration mark shapes, placements, and orientations as long as the registration marks are detectable by the relevant processing equipment.

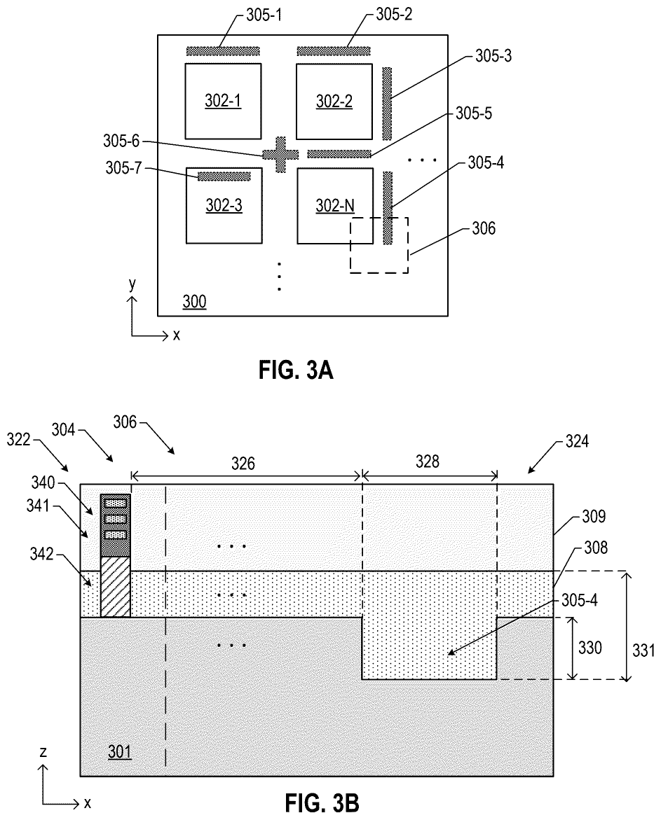

FIG. 3A illustrates a top-down view of an example of a die 300 including patterned trenches for nanoribbon-based transistor registration and alignment. The example die 300 includes areas or regions 302-1-302-N (of which 302-1, 302-2, 302-3, and 302-N are shown) with devices, such as the transistor discussed above with respect to FIG. 1. The regions 302-1-302-N may be referred to as device regions or active regions. In one example, the die includes CMOS circuitry, and thus includes one or more regions of P-type devices and one or more regions of N-type devices. For example, the region 302-1 may be an active NMOS region or area that includes N-type transistors and the region 302-2 may be an active PMOS region or area that includes P-type transistors, where an N-type transistor includes a region (e.g., an S/D region) of a semiconductor material with N-type dopants, and a P-type transistor includes a region (e.g., an S/D region) of a semiconductor material with P-type dopants.

The die 300 also includes patterned insulator-filled trenches 305-1-305-7 in the substrate of the die 300. The trenches may have been used as registration marks for one or more processes during the fabrication of the die 300, and are now filled with an insulator material. Registration marks may generally be located outside of the active regions 302-1-302-N on the die 300, such as shown by the insulator-filled trenches 305-1, 305-2 305-3, 305-4, and 305-6. The area around and/or between active regions 302-1-302-N may be referred to as the frame or nonactive region. In one example the frame lacks devices (or, if devices are present, the devices are not active in the sense that they are not coupled with conductive interconnects to enable operation of the devices). In other examples, registration marks may also or alternatively be located within an active region, such as shown by the insulator-filled trench 305-7 within the region 302-3. In various examples, the registration marks may be located at a distance of at least about 80 nanometers from active devices, or at least about 100 nanometers from active devices (e.g., where the distance is a measurement between a nearest active device and an insulator-filled trench in the x-y plane, as shown in FIG. 3A). For example, a registration mark within an active region may be located at a distance of about 80 nanometers or more from the nearest transistors. In an example in which a registration mark is outside of an active region (e.g., in a frame region adjacent to an active region), the registration mark may be located at a distance of about 100 nanometers or more from the nearest transistors. However, in other examples, registration marks may be located nearer to active devices than 80 nanometers.

Registration marks may be formed in a variety of shapes, such as lines (e.g., where the length is substantially larger than the width) or other shapes (e.g., such as the cross-shaped trench 305-6) that may facilitate registration and alignment of processes in the fabrication of an IC structure. The example illustrated in FIG. 3A depicts substantially rectangular registration marks (e.g., the trenches 305-1, 305-2, 305-3, 305-4, and 305-7), including registration marks that extend along two axes. For example, the trenches 305-1, 305-2, and 305-5 have a length that extends along the x-axis as shown in FIG. 3A. The trenches 305-3, 305-4 have a length that extends along the y-axis as shown in FIG. 3A. A die may include registration marks that extend along a single direction (e.g., only along the x-axis or only along the y-axis), or registration marks that extend along multiple axes (e.g., where some registration marks extend along the x-axis and others extend along the y-axis). In some examples, one or more marks may have a line shape (e.g., where the mark extends generally along a single axis and where the length is greater than the width). In one such example, the opening or trench has a width and a length, where the width and the length are dimensions of the opening in a plane substantially parallel to the substrate (e.g., substantially parallel to the x-y plane shown in FIG. 3A), and where the length is at least about ten times larger than the width or at least about 20 times larger than the width. In some examples, the length of the trench may be in a range of about 1 to 12 micrometers, or in a range of about 2 to 10 micrometers.

As mentioned above, as a result of one or more processes (e.g., a process to form isolation structures), the registration mark trenches in the substrate may be filled with an insulator material. Thus, in some examples, the registration marks appear in the final IC structure as an opening the substrate in a plane below the active regions of transistors (e.g., in a plane below the nanoribbons in which nanoribbon-based transistors are formed), where the opening is filled with a continuous portion of an insulator material. For example, FIG. 3B illustrates an example cross-sectional view of a portion 306 of the die 300.

The example illustrated in FIG. 3B shows a cross-section of an IC structure including a substrate 301 with a first region 322 (which may be an example of an active region or device region) and a second region 324 (which may be an example of a frame) adjacent to and coplanar with the first region 322. The substrate 301 may be an example of the substrate discussed above with respect to FIG. 1. The IC structure includes one or more nanoribbons 304 stacked above one another over the substrate 301 in the first region 322, a nanoribbon-based transistor 341 over the substrate 301 in the region 322, where the transistor 341 includes a channel region 340 in a portion of the one or more nanoribbons 304, and a subfin portion 342 below the one or more nanoribbons (e.g., below a bottom nanoribbon of the stack). An insulator material is around the subfin portion 342. The subfin portion 342 may include the bottom layer of a semiconductor material of the nanoribbon stack and an upper portion of the substrate over which the stack was provided. In some examples, the semiconductor material of a subfin may be replaced (e.g., with an insulator material). Sidewalls of the subfin portion 342 are enclosed by an insulator material 308 commonly referred to as a “shallow trench insulator” (STI). In some examples, the insulator material 308 may be an oxide (e.g., silicon oxide, silicon oxynitride, carbon-doped silicon oxide, carbon-doped silicon oxynitride, or another suitable insulator material including oxygen). An insulator material 309 is depicted as being over the insulator material 308. In one example, the insulator material 309 may be deposited in a later process (e.g., to electrically isolate one or more elements of the transistor 341 from adjacent transistors). The insulator materials 308 and 309 may have substantially the same or different material compositions.

The IC structure of FIG. 3B also includes an opening (e.g., a trench) 305-4 in the second region 324 of the substrate 301. The opening 305-4 may not be immediately adjacent to active transistors, and may be located at a distance 326 away from transistors in the active region, as indicated with the ellipsis in FIG. 3B. In one example, the distance is may be around 100 nanometers or more. In the example illustrated in FIG. 3B, the opening 305-4 is filled with a continuous portion of the insulator material 308, which may be the same insulator material around the subfin portion 342 of the transistor 341. Thus, in the example illustrated in FIG. 3B, the insulator material 308 forms a layer over the substrate in addition to filling the opening 305-4. Said another way, the thickness or height of the insulator material 308 in the opening 305-4 is greater than the sidewall height of the opening. For example, referring to FIG. 3B, a sidewall of the opening 305-4 has a first height 330, where the first height 330 is a dimension of the sidewall in a plane substantially orthogonal to the substrate (e.g., along the z-axis). The continuous portion of the insulator material 308 in the opening 305-4 has a second height (or thickness) 331, where the second height 331 is a dimension of the continuous portion in the plane (e.g., along the z-axis), and where the second height is greater than the first height.

In one example, the height 330 of a sidewall of the opening 305-4 is in a range of about 15 to 85 nanometers, about 20 to 50 nanometers, or about 25 to 35 nanometers. In some examples, the opening 305-4 has a width 328 in a range of about 80 to 200 nanometers, where the width is a dimension of the opening 305-4 in a plane substantially parallel to the substrate (e.g., along the x-axis as shown in FIG. 3B). Openings used as registration marks may have other dimensions than those specifically described (e.g., in some examples, an opening may have a width that is smaller than 80 nanometers or greater than 200 nanometers).

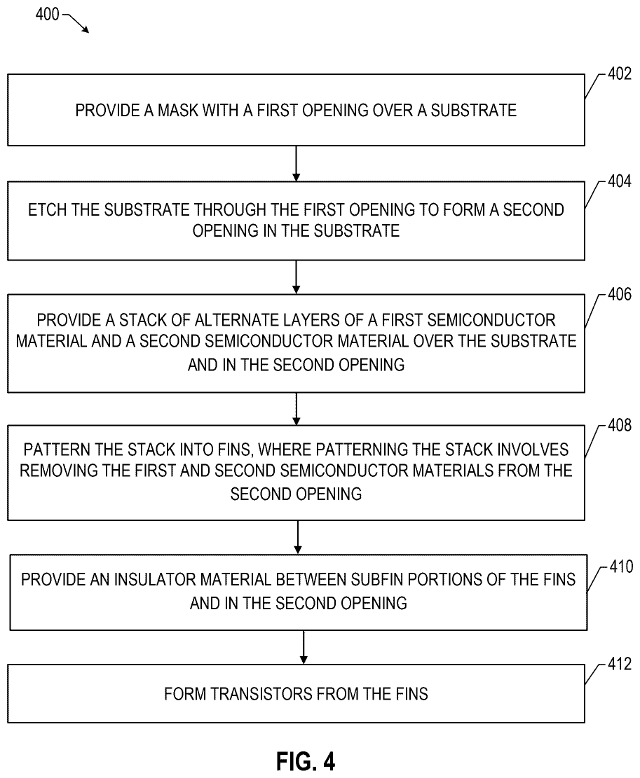

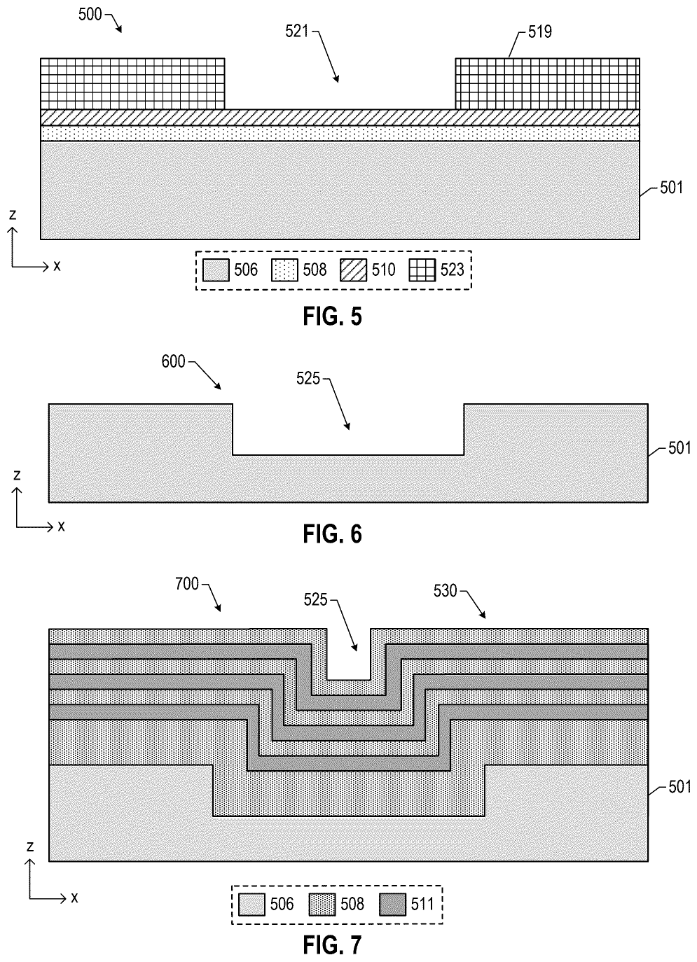

FIG. 4 is a flow diagram of an example method 400 for fabricating an IC structure including patterned trenches for nanoribbon-based transistor registration and alignment. FIGS. 5-7, 8A-8C, 9A-9C, and 10A-10B provide different views at various stages in the fabrication of an example IC structure according to the method of FIG. 4, in accordance with some embodiments. Although the operations of the method of FIG. 4 are illustrated once each and in a particular order, the operations may be performed in any suitable order and repeated as desired. For example, one or more operations may be performed in parallel to fabricate multiple IC structures including patterned trenches for nanoribbon-based transistor registration and alignment substantially simultaneously. In another example, the operations may be performed in a different order to reflect the structure of an IC device in which patterned trenches for nanoribbon-based transistor registration and alignment will be implemented.

In addition, the example fabricating methods of FIG. 4 may include other operations not specifically shown in FIG. 4, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 4 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 4, the method 400 begins with a process 402 of providing a mask with a first opening over a substrate. The IC structure 500 of FIG. 5 is an example resulting structure of the process 402. The IC structure 500 includes a substrate 501, which may include a semiconductor material 506. The substrate 501 may be an example of the substrates discussed above (e.g., with respect to FIG. 1). The IC structure includes a mask 519, which may be formed from one or more layers of material in accordance with any suitable patterning technique. In one example, the mask 519 may include a tri-layer mask, which may include a carbon hard mask material, an anti-reflective coating, and a photoresist material. The example in FIG. 5 further illustrates a layer of an insulator material 508 (e.g., an oxide layer) and a barrier layer 510. In one example, the barrier layer 510 may include a hard mask layer including nitrogen (e.g., titanium nitride or other suitable barrier layer).

The method 400 continues with the process 404 of etching the substrate through the first opening in the mask to form a second opening in the substrate. The IC structure 600 of FIG. 6 is an example resulting structure of the process 404. As can be seen in FIG. 6, the pattern from the mask 519 has been transferred to the substrate 501, which now includes the opening 525. The mask 519, the insulator material 508, and the barrier layer 510 have been removed. In some conventional processes, the method may continue with filling the opening 525 with polysilicon, and the embedded polysilicon region would serve as a registration mark for a subsequent implant process. In contrast, the method 400 involves not filling the opening 525, and the unfilled opening 525 may serve as a registration mark for an implant process.

In an example in which an IC structure including nanoribbon-based transistors are being fabricated, after implant, the method 400 may continue with the process 406 of providing a stack of alternate layers of a first semiconductor material and a second semiconductor material over the substrate in the second opening. The IC structure 700 of FIG. 7 is an example resulting structure of the process 406. The IC structure 700 includes a stack 530 of alternate layers of a first semiconductor material 508 and a second semiconductor material 511. While FIG. 7 illustrates four layers of the semiconductor material 508 and three layers of the second semiconductor material 511 in a stack 530, in other embodiments, any other number of layers may be used as long as they are alternating and include at least three layers of the semiconductor material 508 and at least two layers of the second semiconductor material 511. The upper layers of the semiconductor material 508 will later be formed into nanoribbons stacked above one another. As shown in FIG. 7, in some embodiments, the alternation of layers of the semiconductor material 508 and the second semiconductor material 511 may begin after a bottom layer of the semiconductor material 508 provided over the substrate 501. In one such example, the bottom layer of the semiconductor material 508 may later form a subfin under the stack of nanoribbons. Although the thickness of the bottom layer of the semiconductor material 508 is depicted as being greater than the subsequent layers of the semiconductor material 508 that are formed into nanoribbons via further processing, in other examples, the bottom layer may have a substantially same thickness as another layer of the semiconductor material 508.

The semiconductor material 508 may be any of the semiconductor/channel materials described above with reference to the nanoribbons 104 of FIG. 1 and the nanoribbon 204 of FIGS. 2A-2B. The second semiconductor material 511 may be any suitable material that is etch-selective with respect to the semiconductor material 508 so that, in a later process, the second semiconductor material 511 may be etched away to form nanoribbons of the semiconductor material 508. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the semiconductor material 508 may be silicon while the second material 511 may be a second semiconductor material such as silicon germanium. In another example, the semiconductor material 508 may be silicon germanium, while the second material 511 may be silicon. In other examples, the material 511 may be made of a non-semiconductor material, e.g., of an insulator material, as long as this material is sufficiently etch-selective with respect to the semiconductor material 508.

Thus, the material 511 may be any suitable sacrificial material that is etch-selective with respect to the semiconductor material 508. Selecting the material 511 to be a semiconductor material may be particularly advantageous because it may improve quality of the semiconductor material 508 if the semiconductor material 508 is epitaxially grown on the material 511. In some embodiments, the process 406 may include epitaxially growing layers of the semiconductor material 508 and the second semiconductor material 511 in an alternating manner. In other embodiments, alternate layers of the semiconductor material 508 and the second semiconductor material 511 may be provided in the process 406 using other techniques, such as layer transfer or thin-film deposition. Although FIG. 7 illustrates the same semiconductor material 508 in various layers of the IC structure 700, in general, material compositions of a semiconductor material from which nanoribbons will later be formed in different layers of the IC structure 700 may be different. For example, the semiconductor material 508 of one layer of the IC structure 700 may be silicon while the semiconductor material 508 of another layer of the IC structure 700 may be a III-N semiconductor material such as GaN.

Unlike in conventional processes in which the stack 530 may be provided over a substantially flat substrate (due to filling the opening 525), the stack 530 of FIG. 7 is deposited into the opening 525 in addition to over the substantially flat portions of the substrate. Thus, as can be seen in FIG. 7, the alternate layers of the semiconductor material 508 and the second semiconductor material 511 follow the contours of the opening 525. Although FIG. 7 depicts the opening 525 as having well-defined straight sidewalls and the stack 530 as having well-defined corners in the opening 525, a cross-section of the IC structure 700 may show that the layers of the stack 530 may have a curved shape in the area where the layers conform to the contours of the opening 525. In some examples, the opening 525 with the stack 530 may still be detectable by process equipment to enable registration and alignment. Furthermore, the stack 530 may include fewer defects than a stack 530 that was grown over a substrate with embedded regions of polysilicon.

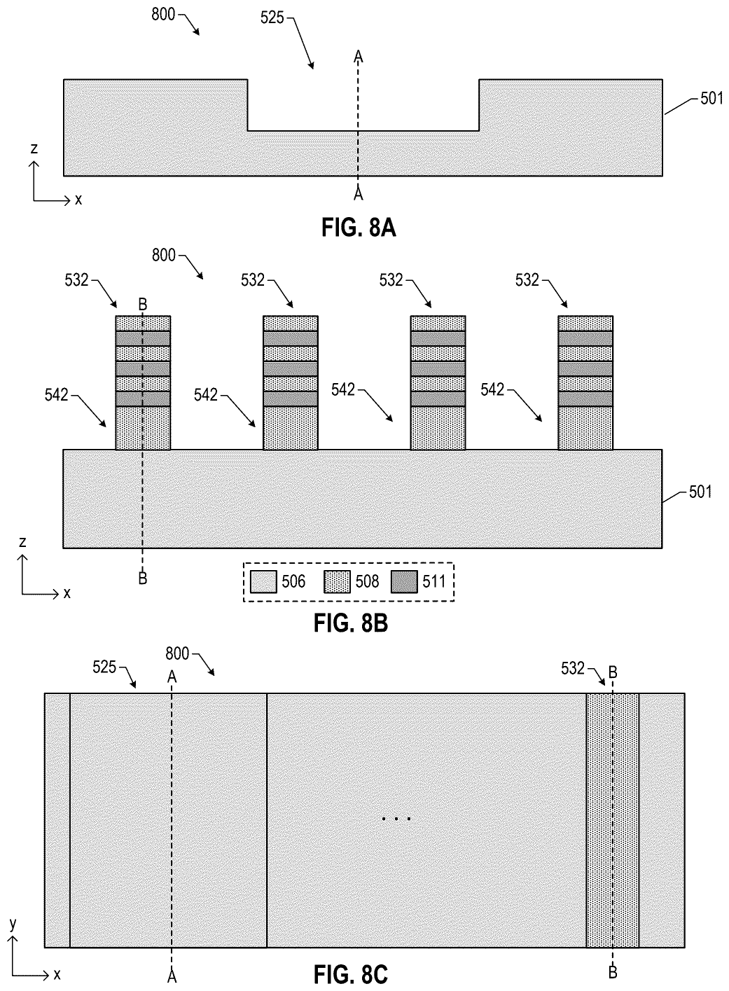

Referring again to FIG. 4, the method 400 includes a process 408 of patterning the stack into fins, where patterning the stack involves removing the first and second semiconductor materials from the second opening. FIGS. 8A-8C illustrate different views of an IC structure 800 after the process 408. FIGS. 8A and 8B illustrate cross-sectional side views of different regions of the IC structure 800, and FIG. 8C illustrates a top-down view of both of the regions of the IC structure 800 illustrated in FIGS. 8A and 8B. Specifically, FIG. 8C illustrates the plane AA through the registration mark opening 525 as shown in FIG. 8A, and a plane BB through a fin 532 as shown in FIG. 8C. An ellipsis is shown in FIG. 8C to indicate that a greater distance than shown may separate the registration mark opening 525 and the fin 532.

In various embodiments, any suitable patterning techniques may be used in the process 408 to form the fins 532, such as, but not limited to, photolithographic or electron-beam (e-beam) patterning, possibly in conjunction with a suitable etching technique, e.g., a dry etch, such as e.g., RF reactive ion etch (RIE) or inductively coupled plasma (ICP) RIE. In some embodiments, the etch performed in the process 408 may include an anisotropic etch, using etchants in a form of e.g., chemically active ionized gas (i.e., plasma) using e.g., bromine (Br) and chloride (CI) based chemistries. In some embodiments, during the etch of the process 408, the IC structure may be heated to elevated temperatures, e.g., to temperatures between about room temperature and 200 degrees Celsius, including all values and ranges therein, to promote that byproducts of the etch are made sufficiently volatile to be removed from the surface.

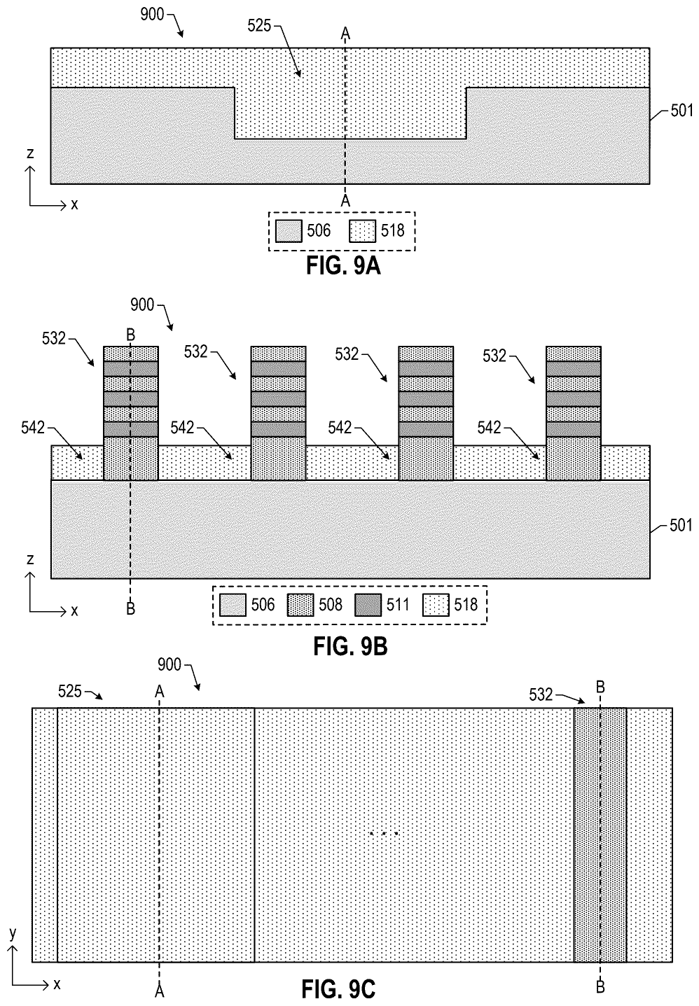

Turning first to FIG. 8A, the portion of the IC structure 800 shown in FIG. 8A includes the registration mark opening 525 (i.e., a similar view to FIG. 7 after the process 408). As can be seen in FIG. 8A, as a result of patterning the fins, the semiconductor materials 508, 511 have been removed from the opening 525. FIG. 8B illustrates an example of a portion of the IC structure 800 that includes fins 532 of the alternate layers of the semiconductor material 508 and the second semiconductor material 511. In some embodiments, the fins 532 may each have a width (e.g., a dimension of the fins measured along the x-axis of the example coordinate system shown in FIG. 9B). The width may be that of the width of the nanoribbons subsequently formed (e.g., the nanoribbon 204 of FIGS. 2A-2B described above). The fins 532 may further have a length (e.g., a dimension of the fins 532 measured along the y-axis of the example coordinate system shown in FIG. 9B, where the y-axis is going into and coming out of the page) suitable to account for the length of the future nanoribbons (e.g., as described above with reference to the length of the nanoribbon 204 of FIGS. 2A-2B). Thus, the fins 532 may be shaped as structures that extend away from the substrate 501 and may each include a subfin 542 at the bottom. In some embodiments, the subfin 542 may include the bottom layer of the semiconductor material deposited at process 406, as well as an upper portion of the substrate 501. In other embodiments, the subfin 542 may include only the semiconductor material 508 and not any portions of the substrate 501. In some embodiments, semiconductor material 508 of the subfin 542 and/or the substrate 501 may be removed and/or replaced with one or more other materials in subsequent processes. In some examples, the fins may be patterned in a different region (e.g., a region of the wafer or die that is to be an active device region) than where the opening 525 is located.

Referring again to FIG. 4, the method 400 continues with the process 410 of providing an insulator material around subfin portions of the fins and in the second opening. FIGS. 9A-9C illustrate different views of an IC structure 900 after the process 410. Specifically, FIG. 9A illustrates a cross-sectional side view similar to FIG. 8A after the process 410, FIG. 9B illustrates a cross-sectional side view similar to FIG. 8B after the process 410, and FIG. 9C illustrates a cross-sectional side view similar to FIG. 8C after the process 410. As can be seen in FIG. 9A, an insulator material 518 fills the opening 525 in addition to forming a layer of the insulator material 518 over the substrate 501. Referring to FIG. 9B, the subfins 542 are portions of the fins 532 that are at least partially enclosed by the insulator material 518. The insulator material 518 may be an example of the STI discussed above with respect to FIG. 3B.

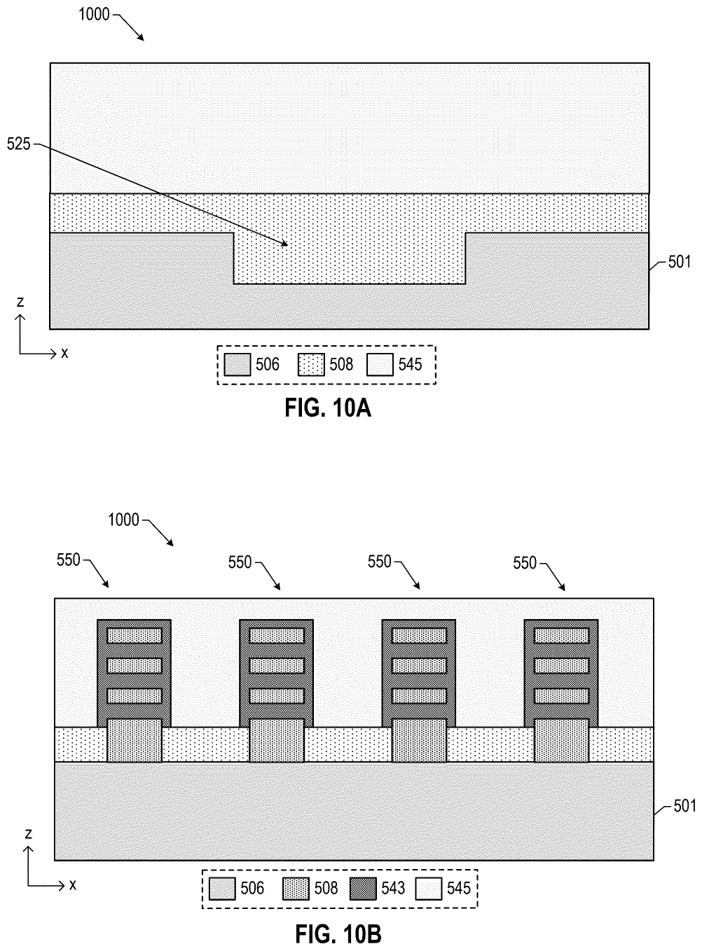

The method 400 continues with the process 412 of forming transistors from the fins. Forming transistors from the fins may involve, among other processes, forming S/D regions in the nanoribbon stacks, removing the semiconductor material 511 to “release” the nanoribbons, providing a gate insulator material around portions of the nanoribbons, and depositing a gate electrode material over the gate insulator material around the nanoribbons. Forming the transistors may involve isolation processes (e.g., etching openings between structures of adjacent transistors and depositing an insulator material). The IC structures 1000 of FIGS. 10A and 10B is an example resulting structure of the process 412. As can be seen in FIG. 10B, the IC structure 1000 includes transistors 550 including a gate electrode material 543 around portions of the nanoribbons. An insulator material 545 is shown as being deposited between adjacent transistors 550. FIG. 10A illustrates the insulator material 545 over the semiconductor material 508. Although the insulator material 545 and the semiconductor material 508 are shown with different shading, the insulator material 545 and the semiconductor material 508 may have the same or different material compositions.

Thus, FIG. 4 illustrates a method 400 for fabricating an IC structure including patterned trenches for nanoribbon-based transistor registration and alignment. Performing the method 400 may result in several features in the final IC structures that are characteristic of the use of the method 400. For example, one such feature is illustrated in an IC structure 1000 shown in FIG. 10A, in which the IC structure includes an opening 525 in a region of the substrate in a plane below one or more nanoribbons, wherein the opening is filled with a continuous portion of an insulator material.

IC devices/structures including patterned trenches for nanoribbon-based transistor registration and alignment as described herein (e.g., as described with reference to FIGS. 2A-2B, 3A-3B, 4, 5-7, 8A-8C, 9A-9C, and 10A-10B) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices/structures disclosed herein, e.g., the IC structures 200A, 200B, 300, and 1000, or any variations thereof, may be included in any suitable electronic component. FIGS. 11-14 illustrate various examples of apparatuses that may include any of the IC devices disclosed herein.

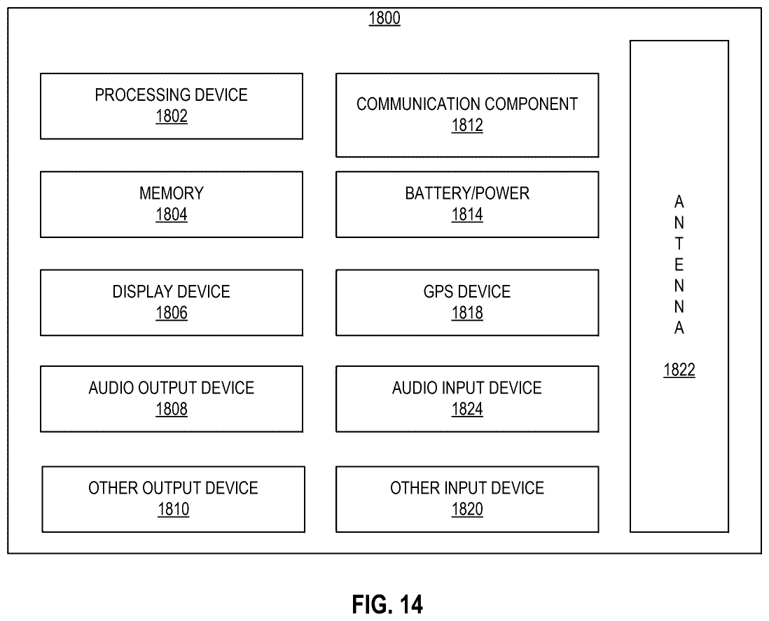

FIG. 11 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 200A, 200B, 300, and 1000, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

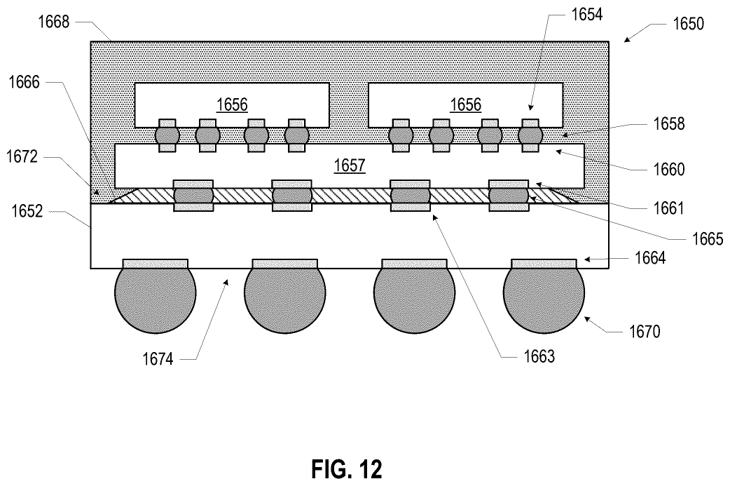

FIG. 12 is a side, cross-sectional view of an example IC package 1650 that may include one or more IC structures in accordance with any of the embodiments disclosed herein (e.g., any of the IC structures 200A, 200B, 300, and 1000, or any variations thereof described herein, or any combination of such IC structures). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

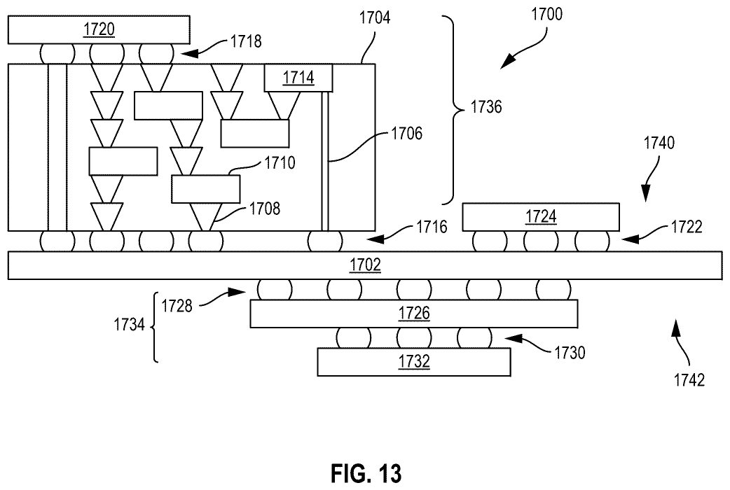

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 13.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 12 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 13 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12 (e.g., may include one or more of the IC structures 200A, 200B, 300, and 1000, or any variations thereof described herein, or any combination of such IC structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 11), an IC device (e.g., any of the IC structures 200A, 200B, 300, and 1000, or any variations thereof described herein, or any combination of such IC structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a substrate including a first region and a second region adjacent to and coplanar with the first region; one or more nanoribbons stacked above one another over the substrate in the first region; a transistor over the substrate in the first region, where the transistor includes a channel region in a portion of the one or more nanoribbons, and a subfin portion below the one or more nanoribbons; an insulator material around the subfin portion; and an opening in the second region of the substrate in a plane below the one or more nanoribbons, where the opening is filled with a continuous portion of the insulator material.

Example 2 provides the IC structure of example 1, where the plane is a first plane, and where: a sidewall of the opening has a first height, where the first height is a dimension of the sidewall in a second plane substantially orthogonal to the substrate; the continuous portion of the insulator material in the opening has a second height, where the second height is a dimension of the continuous portion in the second plane; and the second height is greater than the first height.

Example 3 provides the IC structure of examples 1 or 2, where the plane is a first plane, and where: the opening has a width in a range of about 80 to 200 nanometers, where the width is a dimension of the opening in a second plane substantially parallel to the substrate.

Example 4 provides the IC structure of any one of examples 1-3, where the plane is a first plane, and where: a sidewall of the opening has a height in a range of about 15 to 85 nanometers, where the height is a dimension of the sidewall in a second plane substantially orthogonal to the substrate.

Example 5 provides the IC structure of any one of examples 1-4, where the plane is a first plane, and where: the opening has a width and a length, where the width and the length are dimensions of the opening in a second plane substantially parallel to the substrate; and where the length is at least ten times larger than the width.

Example 6 provides the IC structure of example 5, where: the length is a first length; a nanoribbon of the one or more nanoribbons has a second length, where the second length is a dimension of the nanoribbon in a third plane substantially parallel to the substrate; and the first length is substantially parallel to the second length.

Example 7 provides the IC structure of example 5, where: the length is a first length; a nanoribbon of the one or more nanoribbons has a second length, where the second length is a dimension of the nanoribbon in a third plane substantially parallel to the substrate; and the first length is substantially orthogonal to the second length.

Example 8 provides the IC structure of any one of examples 1-7, where: the second region is outside a device region (e.g., the second region is in a frame area outside active regions, and therefore lacks devices, or if devices are present, those devices lack connection with conductive interconnects).

Example 9 provides the IC structure of any one of examples 1-7, where: the second region is inside a device region.

Example 10 provides the IC structure of any one of examples 1-9, where: the transistor is at a distance from the opening, where the distance is along an axis in the plane, and where the distance is at least 80 nanometers.

Example 11 provides an integrated circuit (IC) die or structure, including a first area (e.g., an active NMOS region) including a first nanoribbon-based transistor over a substrate, where the first nanoribbon-based transistor includes a first semiconductor region that includes N-type dopants; a second area (e.g., an active PMOS region) including a second nanoribbon-based transistor over the substrate, where the second nanoribbon-based transistor includes a second semiconductor region that includes P-type dopants; and a third area (e.g., the frame) between the first area and the second area, where the third area includes a trench in the substrate, where the trench is filled with an insulator material.

Example 12 provides the IC structure of example 11, where: a continuous portion of the insulator material extends from a bottom of the trench to a layer above the substrate.

Example 13 provides the IC structure of examples 11 or 12, where: a sidewall of the trench has a height in a range of about 20 to 50 nanometers, where the height is a dimension of the sidewall in a plane substantially orthogonal to the substrate.

Example 14 provides the IC structure of any one of examples 11-13, where: the trench has a length that extends along an axis between the first region and the second region.

Example 15 provides the IC structure of example 14, where: the length is substantially parallel to a nanoribbon of semiconductor material in the first region.

Example 16 provides the IC structure of example 14, where: the length is substantially orthogonal to a nanoribbon of semiconductor material in the first region.

Example 17 provides the IC structure of any one of examples 11-16, where: the first area is a first active region; the second area is a second active region; and the third area is a nonactive region, where a cross-section of the nonactive region lacks devices.

Example 18 provides the IC structure of any one of examples 11-17, where the first nanoribbon-based transistor and the second nanoribbon based transistor are at a distance from the trench, where the distance is along an axis in a plane substantially parallel with the substrate, and where the distance is at least 80 nanometers, or at least about 100 nanometers.

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a mask with a first opening over a substrate; etching the substrate through the first opening to form a second opening in the substrate; providing a stack of alternate layers of a first semiconductor material and a second semiconductor material over the substrate and in the second opening; patterning the stack into fins, where patterning the stack includes removing the alternate layers of the first semiconductor material and the second semiconductor material from the second opening; providing an insulator material between subfin portions of the fins and in the second opening; and forming transistors from the fins.

Example 36 provides the method of example 35, where: etching the substrate includes etching the opening to a depth of between about 15 to 85 nanometers.

Example 37 provides the method of examples 35 or 36, where: providing the mask includes providing the mask with the opening having a width of about 80 to 200 nanometers.

Example 38 provides the method of any one of examples 35-37, where: providing the mask includes providing the mask with the opening having a length at least ten times larger than its width.

Example 39 provides the method of any one of examples 35-38, where: patterning the stack includes patterning the stack into the fins that are substantially parallel to the opening.

Example 40 provides the method of any one of examples 35-38, where: patterning the stack includes patterning the stack into the fins that are substantially orthogonal to the opening.

Example 41 provides the method of any one of examples 35-40, where: patterning the stack into fins includes patterning the stack into fins in an area at a distance of at least about 80 nanometers from the opening.

Example 42 provides a method according to any one of examples 35-41, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a substrate including a first region and a second region adjacent to and coplanar with the first region;
one or more nanoribbons stacked above one another over the substrate in the first region;
a transistor over the substrate in the first region, wherein the transistor includes:
a channel region in a portion of the one or more nanoribbons, and
a subfin portion below the one or more nanoribbons;
an insulator material around the subfin portion; and
an opening in the second region of the substrate in a plane below the one or more nanoribbons, wherein the opening is filled with a continuous portion of the insulator material.

2. The IC structure of claim 1, wherein the plane is a first plane, and wherein:
a sidewall of the opening has a first height, wherein the first height is a dimension of the sidewall in a second plane substantially orthogonal to the substrate;
the continuous portion of the insulator material in the opening has a second height, wherein the second height is a dimension of the continuous portion in the second plane; and
the second height is greater than the first height.

3. The IC structure of claim 1, wherein the plane is a first plane, and wherein:
the opening has a width in a range of about 80 to 200 nanometers, wherein the width is a dimension of the opening in a second plane substantially parallel to the substrate.

4. The IC structure of claim 1, wherein the plane is a first plane, and wherein:
a sidewall of the opening has a height in a range of about 15 to 85 nanometers, wherein the height is a dimension of the sidewall in a second plane substantially orthogonal to the substrate.

5. The IC structure of claim 1, wherein the plane is a first plane, and wherein:
the opening has a width and a length, wherein the width and the length are dimensions of the opening in a second plane substantially parallel to the substrate, and
the length is at least ten times larger than the width.

6. The IC structure of claim 5, wherein:
the length is a first length;
a nanoribbon of the one or more nanoribbons has a second length, wherein the second length is a dimension of the nanoribbon in a third plane substantially parallel to the substrate; and
the first length is substantially parallel to the second length.

7. The IC structure of claim 5, wherein:
the length is a first length;
a nanoribbon of the one or more nanoribbons has a second length, wherein the second length is a dimension of the nanoribbon in a third plane substantially parallel to the substrate; and
the first length is substantially orthogonal to the second length.

8. The IC structure of claim 1, wherein:
the second region is outside a device region.

9. The IC structure of claim 1, wherein:
the second region is inside a device region.

10. The IC structure of claim 1, wherein:
the transistor is at a distance from the opening, wherein the distance is along an axis in the plane, and wherein the distance is at least 80 nanometers.

11. An integrated circuit (IC) structure, comprising:
a first area including a first nanoribbon-based transistor over a substrate, wherein the first nanoribbon-based transistor includes a first semiconductor region that includes N-type dopants;
a second area including a second nanoribbon-based transistor over the substrate, wherein the second nanoribbon-based transistor includes a second semiconductor region that includes P-type dopants; and
a third area between the first area and the second area, wherein the third area includes a trench in the substrate, wherein the trench is filled with an insulator material.

12. The IC structure of claim 11, wherein:
a continuous portion of the insulator material extends from a bottom of the trench to a layer above the substrate.

13. The IC structure of claim 11, wherein:
a sidewall of the trench has a height in a range of about 20 to 50 nanometers, wherein the height is a dimension of the sidewall in a plane substantially orthogonal to the substrate.

14. The IC structure of claim 11, wherein:
the trench has a length that extends along an axis between the first region and the second region.

15. The IC structure of claim 14, wherein:
the length is substantially parallel to a nanoribbon of semiconductor material in the first region.

16. The IC structure of claim 14, wherein:
the length is substantially orthogonal to a nanoribbon of semiconductor material in the first region.

17. The IC structure of claim 11, wherein:
the first area is a first active region;
the second area is a second active region; and
the third area is a nonactive region, wherein a cross-section of the nonactive region lacks devices.

18. A method of fabricating an integrated circuit (IC) structure, the method comprising:
providing a mask with a first opening over a substrate;
etching the substrate through the first opening to form a second opening in the substrate;
providing a stack of alternate layers of a first semiconductor material and a second semiconductor material over the substrate and in the second opening;
patterning the stack into fins, wherein patterning the stack includes removing the alternate layers of the first semiconductor material and the second semiconductor material from the second opening;
providing an insulator material between subfin portions of the fins and in the second opening; and
forming transistors from the fins.

19. The method of claim 18, wherein:
etching the substrate includes:
etching the opening to a depth of between about 15 to 85 nanometers.

20. The method of claim 18, wherein:
providing the mask includes:
providing the mask with the opening having a width of about 80 to 200 nanometers.
